(19) United States
(12) Patent Application Publication
(10) Pub. No.: US 2013/0207735 A1
(43) Pub. Date: Aug. 15, 2013

(54) VIBRATING DEVICE AND OSCILLATOR

(71) Applicant: SEIKO INSTRUMENTS INC., (US)

(72) Inventor: Yoshifumi YOSHIDA, Chiba-shi (JP)

(73) Assignee: SEIKO INSTRUMENTS INC., Chiba-shi (JP)

(21) Appl. No.: 13/761,842

(22) Filed: Feb. 7, 2013

(30) Foreign Application Priority Data
Feb. 10, 2012 (JP) 2012-027689

(51) Int. Cl. H01L 41/047; H03B 5/32; H01L 41/053

(52) U.S. Cl. CPC H01L 41/0472; H01L 41/053; H03B 5/32
USPC 331/158; 310/348

(57) ABSTRACT

The vibrating device of the invention includes a base member, a lid member joined the base member to constitute a cavity, and a vibrating strip housed in the cavity. The vibrating strip includes a thick center portion and a thin outer peripheral portion, the center portion includes an exciting electrode exciting vibration, and the outer peripheral portion includes terminal electrode electrically connected to exciting electrode and having a thickness larger than that of the exciting electrode. The base member is provided with a connecting portion on the surface thereof, and the connecting portion is connected to the terminal electrode and holds the vibrating strip in a cantilevered manner. Accordingly, the vibrating strip is supported by a very small bonding surface, and a compact vibrating device subjected to little deterioration in frequency characteristics with respect to the temperature change is realized.

### RELATED APPLICATIONS

This application claims priority under 35 U.S.C. §119 to Japanese Patent Application No. 2012-027689 filed on Feb. 10, 2012, the entire content of which is hereby incorporated by reference.

### BACKGROUND OF THE INVENTION

1. Field of the Invention

The present invention relates to a vibrating device and an oscillator provided between two substrates and having a vibrating strip mounted in a cavity thereof.

2. Description of the Related Art

A vibrating device using a crystal vibrator is widely used. The vibrating device using the crystal vibrator is compact and stable in frequency characteristics with respect to a temperature change, and is widely used as a timing source in handheld terminals such as mobile phones or many other types of electronic devices. In recent years, further reduction in size and stability in vibration cycle are required. Therefore, the crystal vibrator is further reduced in size, and is mounted on the substrate by a surface-mounting method.

FIGS. 3A and 3B are explanatory drawings of a crystal vibrator (vibrating device) described in JP-A-2008-109538 (FIG. 1 of JP-A-2008-109538). FIG. 3A is a cross-sectional view of the crystal vibrator, and FIG. 3B is a plan view of the crystal vibrator in a state in which a metallic cover 53 is removed. The crystal vibrator includes a container body 51 formed with a depression, a crystal strip 52 to be mounted on the bottom surface of the depression, and the metallic cover 53 disposed on an upper end of the depression and configured to seal the depression. The crystal strip 52 is supported by the container body 51 with conductive adhesive agents 58 in a cantilevered manner.

The crystal strip 52 has a flat rectangular shape, and includes exciting electrodes 56 configured to excite the crystal strip 52, first drawn portions 57a configured to be electrically connected to the exciting electrodes 56, and second drawn portions 57b electrically connected to the first drawn portions 57a and configured to be installed at corners of the crystal strip 52 on the surface thereof. The exciting electrodes 56 are formed on both surfaces of the crystal strip 52 so as to sandwich the crystal strip 52. The second drawn portions 57b are formed at both corners of a short side of the crystal strip 52, one of the second drawn portions 57b at one of the corners is electrically connected to the exciting electrode 56 formed on one of the surfaces, and the second drawn portion 57b at the other corner is electrically connected to the exciting electrode 56 formed on the other surface. The second drawn portions 57b are electrically connected to crystal terminals 54 via the conductive adhesive agents 58 and are further electrically connected to external terminals 55. Therefore, the crystal strip 52 is fixed at the both corners of the short side thereof to the container body 51 with the conductive adhesive agents 58, and is supported in a cantilevered manner.

According to a mounting method described in JP-A-2008-109538, two portions of the short side of the crystal strip 52 are fixed to a container body 51 with the conductive adhesive agents 58. If the coefficients of thermal expansion of the crystal strip 52 and the container body 51 are different, a stress is applied between two fixed portions with a change in ambient temperature. Consequently, the frequency characteristics are deteriorated with respect to the temperature change. In particular, in the case of an AT cut crystal strip in which a crystal strip 52 is subject to a thickness-shear vibration, when the two portions of the short side of the crystal strip 52 are fixed by the conductive adhesive agents 58, deterioration of frequency characteristics with respect to the ambient temperature change becomes notable.

The vibrating device of this type also holds the interior of the container in a vacuum in order to reduce air resistance. However, when the conductive adhesive agents 58 are used as in JP-A-2008-109538, gas is generated from the conductive adhesive agents 58, and frequency characteristics of the crystal strip 52 fluctuates due to the generated gas. Although the crystal strip 52 is mounted on the container body 51 by heating and melting the conductive adhesive agents 58, the conductive adhesive agents 58 spread at the time of melting, and hence the bonding surface between the crystal strip 52 and the container body 51 can hardly be controlled to a small surface area. In addition, widening of the bonding surface deteriorates the vibratory characteristics of the crystal strip 52. Therefore, reduction in size of the crystal strip 52 is limited. Furthermore, since it takes some time until the conductive adhesive agents 58 are hardened, the crystal strip 52 may be inclined under its own weight while bonding the crystal strip 52 to the container body 51, and hence the vibration may be inhibited due to contact with the package. From the reasons described above, a method of mounting the crystal strip 52 to the container body 51 using the conductive adhesive agent 58 cannot be employed in order to obtain frequency characteristics with high degree of accuracy.

In view of such problems, it is an object of the invention to provide a compact and high accuracy vibrating device configured to inhibit deterioration of frequency characteristics with respect to a change in ambient temperature.

A vibrating device according to the invention includes: a base member; a lid member bonded to the base member to form a cavity; and a vibrating strip configured to be housed in the cavity, wherein the vibrating strip includes a thick center portion and a peripheral portion thinner than the center portion, the center portion includes an exciting electrode configured to excite vibrations, the outer peripheral portion includes a terminal electrode electrically connected to the exciting electrode and having a thickness larger than that of the exciting electrode, the base member includes a connecting portion and a line to be electrically connected to the connecting portion on the surface thereof on the side of the cavity, and the connecting portion is connected to the terminal electrode and is configured to support the vibrating strip in a cantilevered manner.

Preferably, the terminal electrode has a thickness within a range from 2000 angstrom to 4000 angstrom inclusive.

Preferably, the vibrating strip is an AT cut crystal vibrating strip.

Preferably, the connecting portion is formed of a metallic bump.

Preferably, an oscillator includes: the vibrating device described above, and a driving circuit configured to supply a drive signal to the vibrating device.

The vibrating device according to the invention includes: the base member; the lid member bonded to the base member to form the cavity; and the vibrating strip configured to be housed in the cavity, wherein the vibrating strip includes a thick center portion and a peripheral portion thinner than the center portion, the center portion includes the exciting electrode configured to excite vibrations, the outer peripheral portion includes the terminal electrode electrically connected to the exciting electrode and having a thickness larger than that of the exciting electrode, the base member includes the connecting portion and the line to be electrically connected to the connecting portion on the surface thereof on the side of the cavity, and the connecting portion is connected to the terminal electrode and is configured to support the vibrating strip in a cantilevered manner. Accordingly, a compact and high accuracy vibrating device configured to inhibit deterioration of frequency characteristics with respect to a change in ambient temperature is provided.

### BRIEF DESCRIPTION OF THE DRAWINGS

FIGS. 1A and 1B are explanatory drawings illustrating a vibrating device according to a first embodiment of the invention;

FIG. 2 is a schematic top view of an oscillator according to a second embodiment of the invention; and

FIGS. 3A and 3B are explanatory drawings of a crystal vibrator known in the related art.

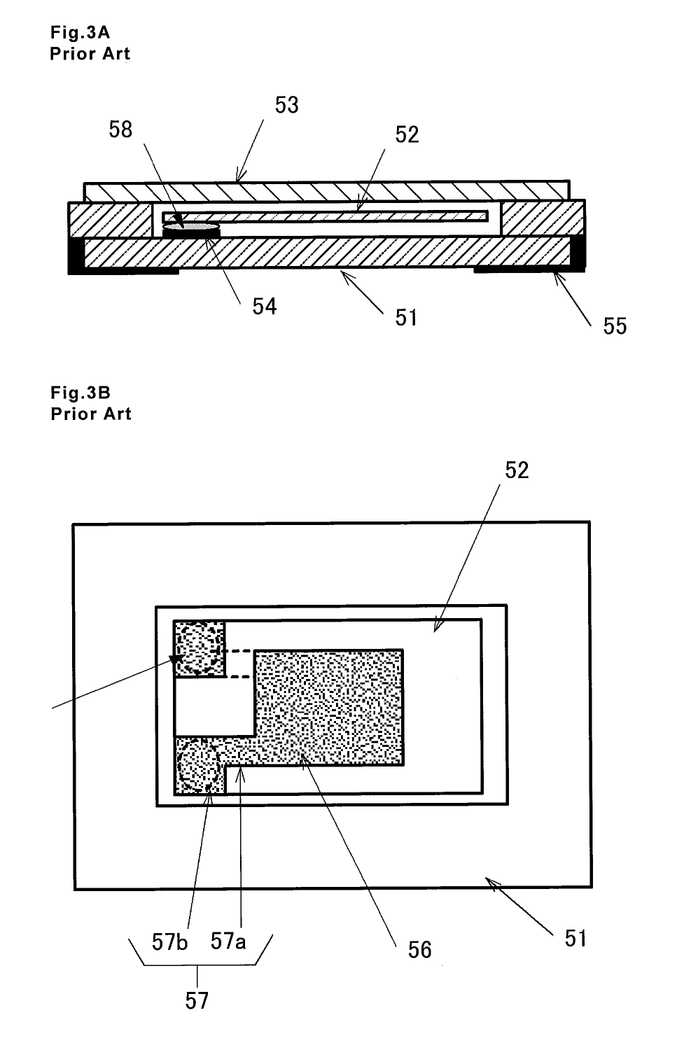

### DETAILED DESCRIPTION OF THE PREFERRED EMBODIMENTS

### First Embodiment

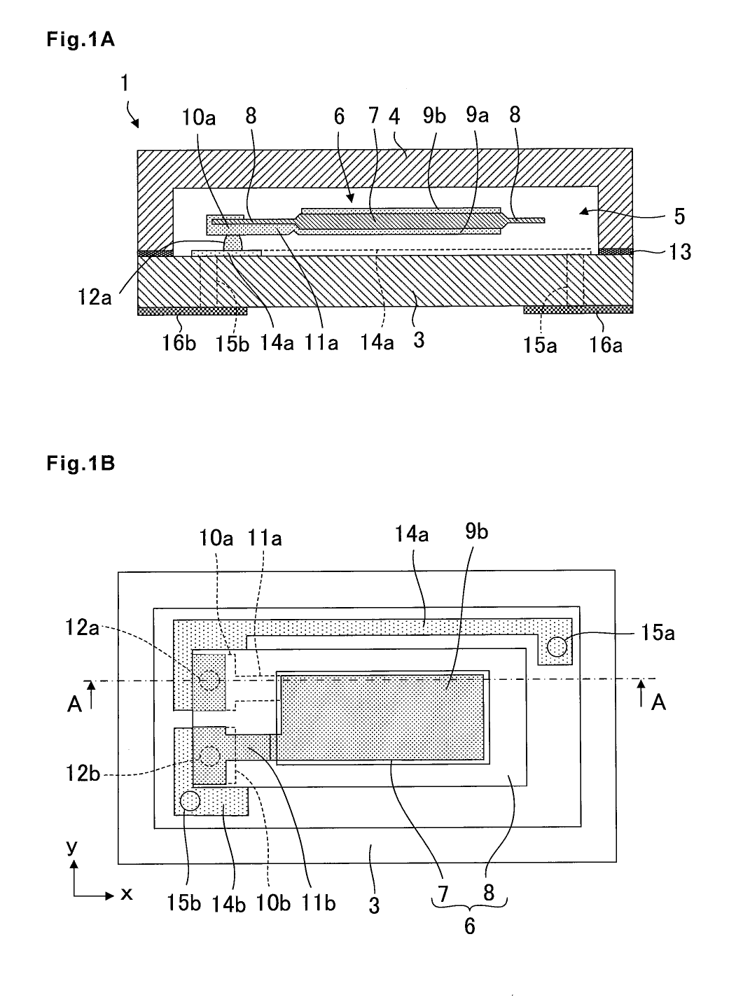

FIGS. 1A and 1B are explanatory drawings of a vibrating device 1 according to a first embodiment of the invention, in which FIG. 1A is a schematic cross-sectional view of a vertical cross section taken along a line A-A in FIG. 1B and viewed in the direction of arrows, and FIG. 1B is a schematic top view of the vibrating device 1 in a state in which a lid member 4 is removed.

As illustrated in FIGS. 1A and 1B, the vibrating device 1 includes a base member 3, the lid member 4 configured to join the base member 3 to constitute a cavity 5, and a vibrating strip 6 to be housed in the cavity 5. The vibrating strip 6 includes a thick center portion 7 and a thin outer peripheral portion 8. The center portion 7 includes exciting electrodes 9a and 9b configured to excite vibrations on both surfaces thereof. The outer peripheral portion 8 is electrically connected to the exciting electrodes 9a and 9b respectively via a line 11a and a line 11b and includes first and second terminal electrodes 10a and 10b thicker than the exciting electrodes 9a and 9b. The base member 3 includes first and second connecting portions 12a and 12b, and first and second lines 14a and 14b to be electrically connected respectively to the first and second connecting portions 12a and 12b on the surface on the side of the cavity 5. The first and second connecting portions 12a and 12b are connected respectively to the first and second terminal electrodes 10a and 10b and support the vibrating strip 6 in a cantilevered manner.

The vibrating strip 6 is the mesa-shaped vibrating strip 6 thicker in the center portion 7 than the outer peripheral portion 8 in the periphery thereof. The mesa-shaped vibrating strip 6 has different resonance frequencies between the center portion 7 and the outer peripheral portion 8. Therefore, influence of the supporting portion on the vibrations of the center portion 7 may be inhibited by supporting the outer peripheral portion 8, so that a compact vibrating device with high degree of accuracy may be realized.

The mesa-shaped vibrating strip 6 is reduced in the thickness of the outer peripheral portion 8 by etching. However, the surface of the outer peripheral portion 8 thinned by etching is a coarse surface. If the thicknesses of the first and second terminal electrodes 10a and 10b formed on the outer peripheral portion 8 are set to have a thickness comparable to the exciting electrodes 9a and 9b, the surfaces of the first and second terminal electrodes 10a and 10b also become coarse surfaces. Even though an attempt is made to connect the first and second terminal electrodes 10a and 10b to the first and second connecting portions 12a and 12b by a flip-chip bonding technique in this state, the connecting strength is insufficient, and the vibrating strip 6 cannot be mounted. Accordingly, the thicknesses of the first and second terminal electrodes 10a and 10b are set to be thicker than that of the exciting electrodes 9a and 9b, and the surfaces of the first and second terminal electrodes 10a and 10b are further smoothened. For example, the thicknesses of the first and second terminal electrodes 10a and 10b are set to fall within a range from 2000 angstrom to 4000 angstrom inclusive. Accordingly, the first and second terminal electrodes 10a and 10b may be connected to the first and second connecting portions 12a and 12b by the flip-chip bonding.

For example, if the flip-chip bonding using metallic bumps is enabled, a circumstance in which a degree of vacuum in the cavity 5 is lowered by generated gas and vibration characteristics is deteriorated as in the case where a conductive adhesive agent is used may be avoided. In addition, by using the metallic bumps as the first and second connecting portions 12a and 12b, increase in bonding surface as the conductive adhesive agent is avoided. Furthermore, in the flip-chip bonding, since the first and second connecting portions 12a and 12b are quickly solidified, impairment of vibrations caused by the vibrating strip 6 inclining with its own weight and hence coming into contact with the base member 3 or the lid member 4 is avoided.

Detailed description will be given below. As illustrated in FIGS. 1A and 1B, the vibrating strip 6 has a flat rectangular shape, and the center portion 7 having a thickness larger than the outer peripheral portion 8 also has a rectangular shape. The center portion 7 includes the exciting electrode 9b on the front surface on the side of the lid member 4 and the exciting electrode 9a on the back surface on the side of the base member 3. The outer peripheral portion 8 includes the first terminal electrode 10a on the surface of the vibrating strip 6 on the side of the base member 3 at a corner between a left side and an upper side thereof, and the second terminal electrode 10b on the surface of the base member 3 at a corner between the left side and a lower side thereof. The first and second terminal electrodes 10a and 10b are electrically connected to the exciting electrodes 9a and 9b formed on both surfaces of the center portion 7 via the lines 11a and 11b, respectively. The first and second terminal electrodes 10a and 10b wrap around the left side end surface of the outer peripheral portion 8 and are formed also on the surface on the side of the lid member 4. The thicknesses of the first and second terminal electrodes 10a and 10b formed on the surface of the outer peripheral portion 8 on the base member 3 side are thicker than that of the exciting electrodes 9a and 9b.

The base member 3 includes the first and second connecting portions 12a and 12b, and the first and second lines 14a and 14b to be electrically connected respectively to the first and second connecting portions 12a and 12b on the surface on the side of the lid member 4. The first connecting portion 12a is provided in the vicinity of the corner between the left side and the upper side of the cavity 5 having a rectangular shape in top view, and the second connecting portion 12b is provided in the vicinity of the corner between the left side and the lower side of the cavity 5, respectively, a first line 14a extends from the vicinity of the corner between the left side and the upper side of the cavity 5 to the vicinity of the corner between the upper side and the right side, and the second line 14b is provided in the vicinity of the corner between the left side and the lower side of the cavity 5. The base member 3 is provided with a first through electrode 15a electrically connected to the first line 14a in the vicinity of the corner between a right side and an upper side of the base member 3 and a second through electrode 15b electrically connected to the second line 14b in the vicinity of a corner between the left side and a lower side thereof. The base member 3 is provided with an external terminal 16a electrically connected to the first through electrode 15a in the vicinity of a right side of the back surface thereof opposite from the lid member 4, and is provided with an external terminal 16b electrically connected to the second through electrode 15b in the vicinity of the left side thereof. The first and second through electrodes 15a and 15b may be formed of FeNi alloy as a material thereof. By using FeNi alloy, high air-tightness is obtained. The external terminals 16a and 16b may be formed of Au/Ni by plate processing.

Consequently, the external terminal 16a is electrically connected to the exciting electrode 9a via the first through electrode 15a, the first line 14a, the first connecting portion 12a, the first terminal electrode 10a, and the line 11a, and the external terminal 16b is electrically connected to the exciting electrode 9b via the second through electrode 15b, the second line 14b, the second connecting portion 12b, the second terminal electrode 10b, and the line 11b. The lid member 4 is bonded to the base member 3 via anode bonding via a bonding member 13, for example, via aluminum. The cavity 5 surrounded by the lid member 4 and the base member 3 is held in a vacuum.

Here, an AT cut crystal strip may be used as the vibrating strip 6. By using the AT cut crystal strip, the vibrating device may be reduced in size. The AT cut crystal strip may be cut out one by one from an AT cut crystal plate by Photolithography and Etching method. A ceramics material, for example, alumina ceramics may be used for the base member 3 and the lid member 4. A glass material may also be used instead of the ceramics material. By using the glass material, a coefficient of thermal expansion is the comparable level as that of the vibrating strip 6, so that deterioration of the frequency characteristics due to a temperature change may further be reduced.

Metallic bumps, for example, gold (Au) bumps may be used for the first and second connecting portions 12a and 12b. Electrodes having a laminated structure of Au and Cr are formed on the center portion 7 and the outer peripheral portion 8, and the formed electrodes are subjected to patterning to form the exciting electrodes 9a and 9b, the lines 11a and 11b and the first and second terminal electrodes 10a and 10b. At the time of electrode accumulation, the electrodes are accumulated in an area of the center portion 7 where the exciting electrodes 9a and 9b are to be formed and an area of the outer peripheral portion 8 where the lines 11a and 11b are formed, then the center portion 7 (and the area where the lines 11a and 11b are to be formed) are masked, and then a metallic film is additionally accumulated on the outer peripheral portion 8. As the exciting electrodes 9a and 9b and the lines 11a and 11b, for example, a two-layer film of Au/Cr is formed to be approximately 1500 angstrom, and as the first and second terminal electrodes 10a and 10b, a two-layer film of Au/Cr is formed to fall within a range from 2000 angstrom to 4200 angstrom inclusive. Then, the vibrating strip 6 is mounted on the first and second connecting portions 12a and 12b of the base member 3 by the flip-chip bonding.

In the relationship between the film thickness and the surface roughness, the surface roughness of the metallic film is increased up to 2000 angstrom. It is because the roughness of the film-formed surface, that is, the roughness of the surface of the outer peripheral portion 8 of the vibrating strip 6 in this application is transferred, so that the roughness of the surface is increased as increase in film thickness. Since the outer peripheral portion 8 is formed by Etching method, the surface roughness is high. Even though an attempt is made to connect the first and second terminal electrodes 10a and 10b to the first and second connecting portions 12a and 12b by a flip-chip bonding technique in this state, the connecting strength is insufficient, and the vibrating strip 6 cannot be mounted. At this time, the surface roughness of the metallic film itself, for example, the surface roughness depending on the grain size of the metallic film is increased. However, transfer of the surface roughness of the outer peripheral portion 8 is reduced. When the metallic film is formed to have a thickness of 2000 angstrom or large, the surface roughness is decreased. It is because the metallic film formed surface does not depend on the roughness of the surface of the outer peripheral portion 8 any longer by increasing the film thickness of the metallic film, and smoothening is proceeded by the formation of the metallic film. In this manner, the surface roughness is gradually decreased with a thickness of 2000 angstrom or larger. Furthermore, when the film thickness is increased to a level larger than 4000 angstrom, the surface roughness is increased. It is because the smoothness cannot be maintained by the increase of the thickness of the metallic film. Therefore, more preferably, the film thickness of the metallic film on the outer peripheral portion 8 is formed within a range of 2000 angstrom to 4200 angstrom inclusive. However, the exciting electrodes 9a and 9b are formed to be thinner than the first and second terminal electrodes 10a and 10b. Accordingly, the surfaces of the first and second terminal electrodes 10a and 10b are smoothened, and hence the flip-chip bonding is facilitated. Since the exciting electrodes 9a and 9b are thin, the influence on the vibrations of the center portion 7 is inhibited, and the extent of deterioration in frequency characteristics is small even when the ambient temperature is changed, so that a compact and high-accuracy vibrating device may be provided.

When the metallic bumps are used for the first and second connecting portions 12a and 12b, the surface area of a holding portion which holds the vibrating strip 6 may be reduced in comparison with a case where a conductive adhesive agent is used. The metallic bump does not generate gas over time unlike the conductive adhesive agent. Therefore, the fluctuation of the frequency characteristics which may be caused by the generated gas is avoided. In comparison with the case where the conductive adhesive agent is used, the first and second connecting portions 12a and 12b are solidified in a short time, and impairment of vibrations caused by the vibrating strip 6 inclining with its own weight and hence coming into contact with the base member 3 is avoided. The lid member 4 and the base member 3 may be bonded via anode bonding via a bonding member 13, for example, an aluminum film. The anode bonding may be performed in a vacuum and the interior of the cavity 5 may be maintained in a vacuum.

In this embodiment, the outline of the vibrating device 1 may be configured to be small because the vibrating strip 6 is mounted on the base member 3 by the flip-chip bonding. For example, a configuration in which the thickness of the center portion 7 of the vibrating strip 6 is approximately 40 μm, the thickness of the outer peripheral portion 8 is approximately 30 μm, the thickness of the cavity 5 is approximately 0.1 mm, the thickness of the base member 3 is 0.2 mm to 0.3 mm, the thickness of the lid member 4 is 0.1 mm to 0.2 mm, and the thickness of the entire vibrating device 1 may be 0.4 mm to 0.5 mm is applicable. Also, the vibrating device 1 may be formed to have a width in the short direction (y-direction) of 1.2 mm to 2.5 mm, and a width in the longitudinal direction (x-direction) of 1.6 mm to 3.2 mm.

### Second Embodiment

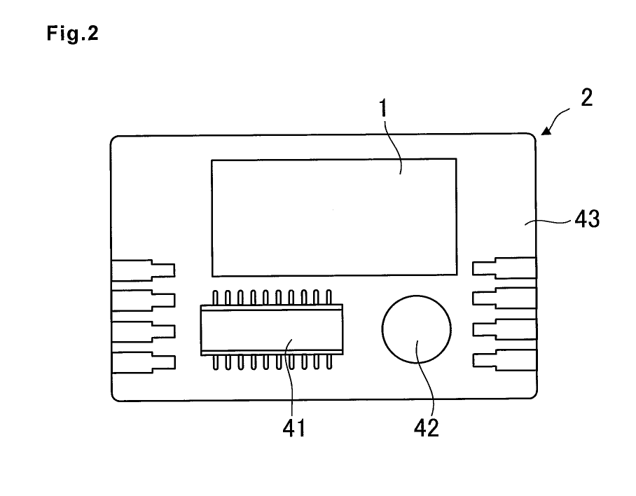

FIG. 2 is a schematic top view of an oscillator 2 according to a second embodiment of the invention. In the second embodiment, the oscillator 2 is configured to includes the vibrating device 1 of the first embodiment described above built therein. As illustrated in FIG. 2, the oscillator 2 includes a substrate 43, the vibrating device 1 disposed on the substrate, an integrated circuit 41, and an electronic component 42. The vibrating device 1 generates a signal having a certain frequency on the basis of a drive signal supplied to the external terminal, the integrated circuit 41 and the electronic component 42 process the signal having the certain frequency supplied from the vibrating device 1, and generate a reference signal such as a clock signal. The vibrating device 1 according to the invention has high reliability and may be formed to be compact, so that the entire oscillator 2 may be formed to be further compact.

What is claimed is:

1. A vibrating device comprising:
a base member;
a lid member bonded to the base member to form a cavity; and
a vibrating strip configured to be housed in the cavity, wherein
the vibrating strip includes a thick center portion and an outer peripheral portion thinner than the center portion,
the center portion includes an exciting electrode configured to excite vibrations,
the outer peripheral portion includes a terminal electrode electrically connected to the exciting electrode and having a thickness larger than that of the exciting electrode,
the base member includes a connecting portion and a line to be electrically connected to the connecting portion on the surface thereof on the side of the cavity, and
the connecting portion is connected to the terminal electrode and is configured to support the vibrating strip in a cantilevered manner.

2. The vibrating device according to claim 1, wherein the terminal electrode has a thickness within a range from 2000 angstrom to 4000 angstrom inclusive.

3. The vibrating device according to claim 1, wherein the vibrating strip is an AT cut crystal vibrating strip.

4. The vibrating device according to claim 2, wherein the vibrating strip is an AT cut crystal vibrating strip.

5. The vibrating device according to claim 1, wherein the connecting portion is formed of a metallic bump.

6. The vibrating device according to claim 2, wherein the connecting portion is formed of a metallic bump.

7. The vibrating device according to claim 3, wherein the connecting portion is formed of a metallic bump.

8. The vibrating device according to claim 4, wherein the connecting portion is formed of a metallic bump.

9. An oscillator comprising:
the vibrating device according to claim 1, and
a driving circuit configured to supply a drive signal to the vibrating device.
